(19) United States
(12) Patent Application Publication
(10) Pub. No.: US 2026/0026016 A1
(43) Pub. Date: Jan. 22, 2026

(54) METHOD OF MAKING AN ELECTRODE WITHOUT A LITHOGRAPHY MASK

(71) Applicant: Tokyo Electron Limited, Tokyo (JP)

(72) Inventors: Sara Otsuki, Albany, NY (US); Soo Doo Chae, Albany, NY (US); Hirokazu Aizawa, Albany, NY (US); Ryota Yonezawa, Albany, NY (US); Jason Marion, Albany, NY (US)

(21) Appl. No.: 18/778,624

(22) Filed: Jul. 19, 2024

(51) Int. Cl. H10D 1/00; H10D 1/68

(52) U.S. Cl. CPC H10D 1/043; H10D 1/716

(57) ABSTRACT

A method for forming a semiconductor device can include forming a first sacrificial layer of silicon nitride on a first insulator layer of a first metal-insulator-metal (MIM) intermediate structure, where the first MIM intermediate structure further includes a first electrode, where the first insulator layer is on the first electrode, forming a second sacrificial layer of silicon dioxide on the first sacrificial layer, removing the second sacrificial layer and the first sacrificial layer, where the removing at least concludes with etching using a first etch chemistry containing chlorine and nitrogen, and while a residue of chlorine and nitrogen remains on an exposed surface of the first insulator layer after the etching with the first etch chemistry, initiating depositing of a second electrode on the first insulator layer.

### TECHNICAL FIELD

The present disclosure relates generally to methods for manufacturing semiconductor devices, and more particularly, processes of making an electrode without a lithography mask for manufacturing semiconductor devices.

### BACKGROUND

Metal-Insulator-Metal (MIM) devices are a class of semiconductor components characterized by their structure, which typically includes two metal electrodes separated by an insulating layer. Some MIM devices can exploit quantum mechanical tunneling and capacitive effects. The insulating layer, which is typically a high-k dielectric material, is sometimes thin enough to allow electrons to tunnel through when a voltage is applied across the metal electrodes. In some applications, the thickness of the insulating layer can be in the range of a few nanometers. The thickness and material of the insulating layer can determine the electrical properties of a MIM device. Some MIM devices are known for their high-speed response, low power consumption, and high breakdown voltages, which can make MIM devices suitable for a variety of advanced electronic applications.

One example use of MIM devices is in high-frequency and microwave circuits, where their fast switching capabilities are highly beneficial. Another example use of MIM devices are capacitors in radio frequency (RF) and microwave systems due to their ability to handle high frequencies with minimal loss. MIM capacitors can be integral components in analog and mixed-signal integrated circuits (ICs), where they can provide stable capacitance values and excellent performance over a wide range of frequencies. Such stability and precision can be useful for maintaining the integrity of signals in communication devices, including smartphones, satellite systems, and other wireless communication technologies.

Another example use of MIM devices is in memory storage technologies, such as in resistive random-access memory (ReRAM). In ReRAM, MIM structures can be used to create memory cells where data is stored based on the resistance states of the insulating layer. By applying different voltage levels, the insulating material can switch between high and low resistance states, representing binary data. ReRAM can be used as non-volatile memory due to its high speed, low power consumption, and excellent scalability. MIM devices can be used in various sensing applications, such as in chemical and biological sensors, where sensitivity to changes in the surrounding environment can be harnessed for precise detection and measurement.

As device sizes scale down to smaller sizes, multiple lithography steps can be difficult to use while maintaining alignments between existing features and newly patterned features during the successive building of stacked layers for a MIM device.

### SUMMARY

In accordance with an embodiment of the present disclosure, a method for forming a semiconductor device can include: forming a first sacrificial layer of silicon nitride on a first insulator layer of a first metal-insulator-metal (MIM) intermediate structure, where the first MIM intermediate structure further includes a first electrode, where the first insulator layer is on the first electrode; forming a second sacrificial layer of silicon dioxide on the first sacrificial layer to form a second MIM intermediate structure; removing the second sacrificial layer and the first sacrificial layer, where the removing at least concludes with etching using a first etch chemistry containing chlorine and nitrogen; and while a residue of chlorine and nitrogen remains on an exposed surface of the first insulator layer after the etching with the first etch chemistry, initiating depositing of a second electrode on the first insulator layer.

In accordance with an embodiment of the present disclosure, a method for forming a semiconductor device can include: providing a first intermediate structure having a hole formed therein; conformally depositing a first sacrificial layer including a nitride material in the hole; forming a second sacrificial layer including an oxide material on the first sacrificial layer to form a second intermediate structure; removing the second sacrificial layer and at least part of the first sacrificial layer, where the removing at least concludes with etching using a first etch chemistry containing chlorine and nitrogen; and while a residue of chlorine and nitrogen remains on a bottom of the hole after the etching with the first etch chemistry, initiating depositing of at least a first portion of an electrode layer at the bottom and sidewalls of the hole and on top surfaces outside of and adjacent the hole, where after depositing the electrode layer, a first thickness of the electrode layer at the bottom of the hole is greater than a second thickness of the electrode layer on the top surfaces outside of and adjacent the hole.

In accordance with an embodiment of the present disclosure, a method for forming a semiconductor device can include: forming a first sacrificial layer of silicon nitride on a first insulator layer of a first metal-insulator-metal (MIM) intermediate structure, where the first MIM intermediate structure further includes a first metal electrode formed on a bottom and at least partially on sidewalls of a hole, where the first insulator layer is conformally on and covering the first metal electrode; forming a second sacrificial layer of silicon dioxide on the first sacrificial layer to form a second MIM intermediate structure; baking the second MIM intermediate structure; removing the second sacrificial layer and the first sacrificial layer, where the removing at least concludes with etching using a first etch chemistry containing chlorine and nitrogen; while a residue of chlorine and nitrogen remains on an exposed surface of the first insulator layer after the etching with the first etch chemistry, initiating depositing of a second metal electrode layer on the first insulator layer at the bottom and sidewalls of the hole and on a top surface outside of and adjacent the hole, the second metal electrode layer includes a metal nitride layer being first deposited for the depositing of the second metal electrode layer, and where after the depositing of the second metal electrode layer, a first thickness of the second metal electrode layer at the bottom of the hole is at least five times greater than a second thickness of the second metal electrode layer on the top surface outside of and adjacent the hole; and etching the second metal electrode layer to remove the second thickness on at least part of the top surface outside of and adjacent the hole, while retaining at least part of the first thickness of the second metal electrode layer at the bottom of the hole, to form a second metal electrode for a MIM device from the second metal electrode layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1-8 are cross-section views illustrating intermediate structures of a semiconductor device made using a method according to an embodiment of the present disclosure;

FIGS. 9-14 are cross-section views illustrating intermediate structures of a semiconductor device made using a method according to an embodiment of the present disclosure;

FIG. 15 illustrates a flow chart implementing the forming of an electrode for a MIM device in accordance with an embodiment of the present disclosure;

FIG. 16 illustrates a flow chart implementing the forming of an electrode for a MIM device in accordance with an embodiment of the present disclosure; and

FIG. 17 illustrates a flow chart implementing the forming of an electrode for a MIM device in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure, certain elements may be discussed, referred to, and actually plural, but only shown as a singular example in the drawings, even though that single example is among a set of a plurality. Similarly, certain elements may be discussed, referred to, and shown as singular, but may be plural or may be part of a set of a plurality of the same. Given that a structure and feature is typically repeated many times in a semiconductor device, one of ordinary skill in the art to which the present disclosure pertains can realize and understand such alternating between singular and plural.

Typically, during the formation of multiple layers of a MIM device, a new lithography mask for a top electrode will be patterned in alignment with a bottom electrode and/or a hole in which the MIM device is formed. However, as device sizes scale down to smaller sizes, multiple lithography steps can be difficult to align between existing features and newly patterned features during the successive building of stacked layers for a MIM device.

The minimum dimension of patterned features can be shrunk periodically to roughly double the component density at each successive technology node, thereby reducing the cost per function. Innovations in patterning, such as immersion deep ultraviolet (i-DUV) lithography, multiple patterning and 13.5 nm wavelength extreme ultraviolet (EUV) optical systems have brought some critical dimensions down a scale less than ten nanometers. Holes for MIM devices, such as in memory devices, can be formed using EUV with a critical dimension (e.g., hole diameter) as small as about 20 nm, for example. Thus, forming and patterning a photolithography mask to align precisely with a set of 20-40 nm holes can be very difficult to achieve consistently with high reliability and repeatability.

An embodiment of the present disclosure can solve the above noted problem by providing a method of forming an electrode for a MIM device in a hole without the use of a lithography mask. Eliminating lithography mask patterning operations in a process integration for manufacturing a semiconductor device can provide advantages, such as reduced process complexity and improved yield.

In some embodiments of the present disclosure, a method for forming a semiconductor device can include: providing a first intermediate structure having a hole formed therein; conformally depositing a first sacrificial layer of silicon nitride in the hole; forming a second sacrificial layer of silicon dioxide (e.g., spin-on-glass) on the first sacrificial layer to form a second intermediate structure; removing the second sacrificial layer and at least part of the first sacrificial layer, where the removing at least concludes with etching using a first etch chemistry containing chlorine and nitrogen; and while a residue of chlorine and nitrogen remains on a bottom surface of the hole after the etching with the first etch chemistry, initiating the depositing of a metal layer at the bottom and sidewalls of the hole and on top surfaces outside of and adjacent the hole, where after the depositing of the metal layer, a first thickness of the metal layer at the bottom of the hole is greater than (e.g., 5-6 times greater than) a second thickness of the metal layer on the top surfaces outside of and adjacent the hole. Because the metal layer forms at the bottom of the hole with a first thickness that is about 5-6 times greater than a second thickness outside of the hole, the second thickness can be etched back to form a metal electrode without the need to use a lithography mask.

In some embodiments of the present disclosure, a method for forming a semiconductor device can include: forming a first sacrificial layer of silicon nitride on a first insulator layer of a first metal-insulator-metal (MIM) intermediate structure, where the first MIM intermediate structure further includes a first electrode, where the first insulator layer is on the first electrode; forming a second sacrificial layer of silicon dioxide on the first sacrificial layer to form a second MIM intermediate structure; removing the second sacrificial layer and the first sacrificial layer, where the removing at least concludes with etching using a first etch chemistry containing chlorine and nitrogen; and while a residue of chlorine and nitrogen remains on an exposed surface of the first insulator layer after the etching with the first etch chemistry, initiating the depositing of a second electrode on the first insulator layer. The residue of chlorine and nitrogen remaining on an exposed surface of the first insulator layer can cause the second electrode to form faster and thicker where that residue remains, thereby creating a variance of thicknesses for the layer of the second electrode. Such variance of thicknesses allows portions of the layer of the second electrode to be etched away, resulting in the second electrode being formed/deposited without the need for a photolithography mask for that second electrode.

In some embodiments of the present disclosure, a method for forming a semiconductor device can include: forming a first sacrificial layer of silicon nitride on a first insulator layer of a first metal-insulator-metal (MIM) intermediate structure, where the first MIM intermediate structure further includes a first metal electrode formed on a bottom and at least partially on sidewalls of a hole, where the first insulator layer is conformally on and covering the first metal electrode; forming a second sacrificial layer of silicon dioxide on the first sacrificial layer to form a second MIM intermediate structure; baking the second MIM intermediate structure; removing the second sacrificial layer and the first sacrificial layer, where the removing at least concludes with etching using a first etch chemistry containing chlorine and nitrogen; while a residue of chlorine and nitrogen remains on an exposed surface of the first insulator layer after the etching with the first etch chemistry, initiating depositing of a second metal electrode layer on the first insulator layer at the bottom and sidewalls of the hole and on a top surface outside of and adjacent the hole, where the second metal electrode layer includes a metal nitride layer (e.g., TiN) being first deposited for the depositing of the second metal electrode layer, and where after the depositing of the second metal electrode layer, a first thickness of the second metal electrode layer at the bottom of the hole is at least five times greater than a second thickness of the second metal electrode layer on the top surface outside of and adjacent the hole; and etching the second metal electrode layer to remove the second thickness on at least part of the top surface outside of and adjacent the hole, while retaining at least part of the first thickness of the second metal electrode layer at the bottom of the hole, to form a second metal electrode for a MIM device from the second metal electrode layer. After the etching of the second metal electrode layer, portions of the second metal electrode layer can remain on at least part of the sidewalls of the hole, such that the second metal electrode is on the bottom of the hole and also on at least part of the sidewalls of the hole. Accordingly, the second metal electrode can be formed without the need to use a lithography mask for that second metal electrode.

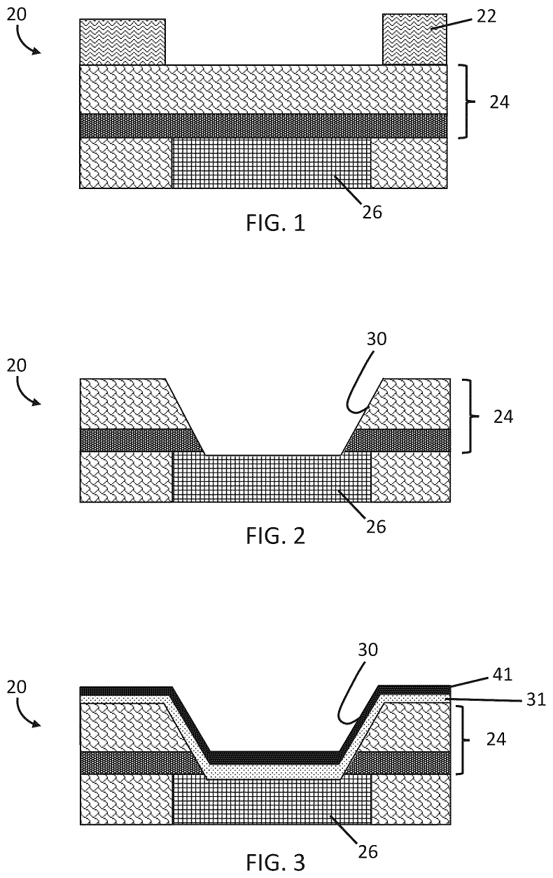

For simplification and illustration purposes, FIGS. 1 to 14 are merely showing some portions of a substrate and of intermediate structures for a semiconductor device that can be relevant to a method of making a semiconductor device according to some embodiments of the present disclosure. Accordingly, in FIGS. 1 to 14, to simplify the drawings, as can be readily understood by one of ordinary skill in the pertinent art, additional layers and structures for a semiconductor device made before, under, below, or adjacent the intermediate structures shown in the drawings can be omitted and not shown. And accordingly, in FIGS. 1 to 14, to simplify the drawings, as can be readily understood by one of ordinary skill in the pertinent art, additional layers and structures for a semiconductor device made after, over, above, or adjacent the intermediate structures shown in the drawings can be omitted and not shown. Furthermore, in an actual completed semiconductor device cross-section, the intermediate structures, or remnants thereof, that are illustrated and represented in the drawings of the present disclosure in a simplified manner as having squared edges, rectangular block shapes, and/or linear shapes can be actually pointed (e.g., bottoms of the holes), more rounded, more curved shaped, and less linear shaped (e.g., scalloped).

FIGS. 1-14 are various views of various intermediate structures of example semiconductor devices, schematically showing a processing sequence for forming the intermediate structures of the example semiconductor devices using methods according to some example embodiments of the present disclosure. In FIGS. 1 to 14, the example semiconductor devices being built include MIM devices being formed in holes for making capacitors in the substrate. However, some embodiments of the present disclosure can be applied to making other types or portions of intermediate structures for other types and kinds of semiconductor devices.

Referring to FIG. 1, an intermediate structure can include a substrate 20 having a patterned photolithography mask 22 formed over other layers that can vary per design and device(s) being built. The substrate 20 can include a dielectric layer 24 over an underlying contact 26 (or conductor). The substrate 20 can include a semiconductor material or a combination of semiconductor materials, such as silicon nitride (SiN), silicon dioxide (SiO₂), silicon, silicon germanium, silicon carbide, or any combination thereof, for example. The substrate 20 can be part of any suitable wafer type or structure, including a silicon wafer or a silicon-on-insulator (SOI) wafer, for example.

Referring to FIG. 2, a hole 30 can be patterned and etched in the dielectric layer 24 of the substrate 20 opening to the underlying contact 26, and the photolithography mask 22 can be removed. Although the hole 30 shown in FIG. 2 has slanted sidewalls, a hole can have more vertical, substantially vertical, or vertical sidewalls, with higher aspect ratios than the simplified example hole 30 illustrated in FIG. 2, for example.

Referring to FIG. 3, a first metal electrode layer 31 for a first metal electrode of a MIM device can be conformally deposited in the hole 30, covering a bottom and sidewalls of the hole 30, for example. A first insulating layer 41 can be conformally deposited in the hole 30 on the first metal electrode layer 31, which can form a first MIM intermediate structure of a MIM device.

Even though the first metal electrode layer 31 is illustrated and represented in the drawings as a single layer of one material, in some embodiments, this first metal electrode layer 31 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the first metal electrode layer 31 can be formed using PVD, CVD, PECVD, ALD, PEALD, or any combination thereof, for example. In some embodiments, such material(s) of a given first metal electrode layer 31 can include W, WSi, W(Si)N, TiN, TaN, CrN, NbN, VN, MON, and Ti(Al)N, layers thereof, mixtures thereof, laminates thereof, or generally any combination thereof, for example. The thickness of the first metal electrode layer 31 can depend on the process flow integration. For example, the first metal electrode layer 31 can have a thickness in a range of 5 nm to 100 nm. In some embodiments, the first metal electrode layer 31 can include a metal nitride layer deposited first with another metal layer deposited second. For example, in some embodiments, the first metal electrode layer 31 can include a titanium nitride layer deposited first with a tungsten layer deposited secondly on the titanium nitride layer.

Even though the first insulating layer 41 is illustrated and represented in the drawings as a single layer of one material, in some embodiments, this first insulating layer 41 can be a single layer of one material, a single layer of a mix of multiple materials, multiple layers of one material, multiple layers of a same material or mix of multiple materials, or multiple layers of different materials, for example. In some embodiments, the material(s) and thickness of a given first insulating layer 41 can be selected to in view of providing capacitor characteristics for a given device specification/design. In some embodiments, such material(s) of a given first insulating layer 41 can include a high-k dielectric material, such as hafnium oxide (HfO₂), aluminum oxide (Al₂O₃), zirconium oxide (ZrO₂), tantalum pentoxide (Ta₂O₅), titanium dioxide (TiO₂), yttrium oxide (Y₂O₃), lanthanum oxide (La₂O₃), silicon nitride (Si₃N₄), barium strontium titanate (BST), strontium titanate (SrTiO₃), bismuth strontium titanium oxide (Bi₄Ti₃O₁₂), hafnium silicate (HfSiO₄), zirconium silicate (ZrSiO₄), praseodymium oxide (Pr₂O₃), gadolinium oxide (Gd₂O₃), cerium oxide (CeO₂), layers thereof, mixtures thereof, laminates thereof, or generally any combination thereof, for example. The thickness of the first insulating layer 41 can depend on the process flow integration and MIM device specification/design. For example, the first insulating layer can have a thickness in a range of 2 nm to 30 nm.

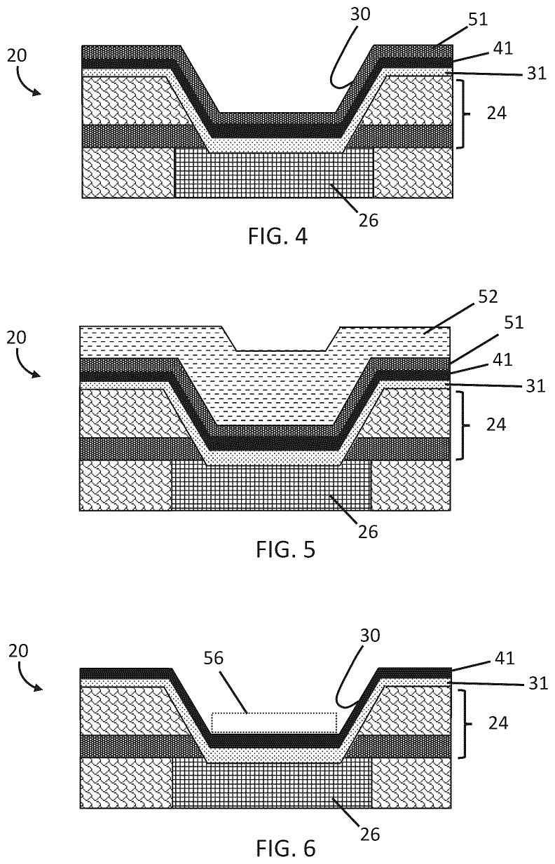

Referring to FIG. 4, a first sacrificial layer 51 can be deposited on the first insulating layer 41. The first sacrificial layer 51 can be silicon nitride, for example. Even though the first sacrificial layer 51 is illustrated and represented in the drawings as a single layer of one material, in some embodiments, this first sacrificial layer 51 can be a single layer of one material, a single layer of a mix of multiple materials, multiple layers of one material, multiple layers of a same material or mix of multiple materials, or multiple layers of different materials, for example. In some embodiments, such material(s) of a given first sacrificial layer 51 can include nitride-containing material, such as silicon nitride (Si₃N₄ or SiN), silicon oxynitride (SiON), aluminum nitride (AlN), gallium nitride (GaN), titanium nitride (TiN), tantalum nitride (TaN), hafnium nitride (HfN), zirconium nitride (ZrN), layers thereof, mixtures thereof, laminates thereof, or generally any combination thereof, for example. In some embodiments, the first sacrificial layer can be formed using PVD, CVD, PECVD, ALD, PEALD, or any combination thereof, for example. The thickness of the first sacrificial layer can be about 20 nm, or in a range of 18 nm to 30 nm, for example.

Referring to FIG. 5, a second sacrificial layer 52 can be deposited on the first sacrificial layer 51. In some embodiments, the second sacrificial layer 52 can be formed by spin coating to form a spin-on-glass layer. The second sacrificial layer 52 can be silicon dioxide (SiO₂), for example. Even though the second sacrificial layer 52 is illustrated and represented in the drawings as a single layer of one material, in some embodiments, this second sacrificial layer 52 can be a single layer of one material, a single layer of a mix of multiple materials, multiple layers of one material, multiple layers of a same material or mix of multiple materials, or multiple layers of different materials, for example. In some embodiments, the second sacrificial layer 52 can be formed using PVD, CVD, PECVD, ALD, PEALD, or any combination thereof, for example. In some embodiments, the goal can be for the second sacrificial layer 52 to fill the hole 30 of the MIM device and/or to provide planarization of the top surface of the intermediate structure after forming the second sacrificial layer 52. For example, material(s) of the second sacrificial layer 52 can be deposited in a liquid-like manner (e.g., spin-on-glass, flowable oxide) and material can be selected that is able to be etched/removed at same or similar rate as the first sacrificial layer 51 (e.g., using reactive ion etching (RIE) and/or plasma etching), for example. The thickness of the second sacrificial layer 52 can depend on the device/via/hole structure, and can be about 50 nm (or more) thicker than the via/hole depth, for example.

After depositing the second sacrificial layer 52, the intermediate structure (e.g., intermediate structure shown in FIG. 5) can be baked at a temperature in a range of 400° C. to 450° C., to cure and/or heat treat the intermediate structure (e.g., curing the second sacrificial layer 52), for example.

Referring to FIG. 6, the second sacrificial layer 52 and the first sacrificial layer 51 can be removed using a first etch chemistry containing chloride (Cl₂) and nitrogen (N₂). The etching can be a wet etch, a dry etch, reactive ion etching (RIE), plasma etching, or any combination thereof, for example. Other etch processes using other etch chemistries can be used during the removal of the second sacrificial layer 52 and the first sacrificial layer 51, with the removing at least concluding with etching using the first etch chemistry containing chlorine and nitrogen.

In some embodiments, the etching to remove the second sacrificial layer 52 and the first sacrificial layer 51 using a first etch chemistry containing chloride (Cl₂) and nitrogen (N₂), can have the following process conditions, for example: a step process time of about 50 seconds, or in a range of 5 seconds to 20 mins; a chamber pressure of about 50 mTorr, or in a range of 5 mTorr to 800 mTorr; an upper radio frequency (RF) Power of about 100 watts, or in a range of 50 watts to 3000 watts; a lower RF Power of about 100 watts, or in a range of 50 watts to 3000 watts; a temperature of about 80° C., or in a range of −10° C. to 120° C.; a flow rate of Cl₂ of about 10 SCCM, or in a range of 1 SCCM to 1000 SCCM; and a flow rate of N₂ of about 6 SCCM, or in a range of 1 SCCM to 1000 SCCM. In some embodiments, all of the second sacrificial layer and the first sacrificial layer can be removed. In some embodiments, the etching of the second sacrificial layer 52 and the first sacrificial layer 51 can be a timed etch.

After the etching using the first etch chemistry containing chlorine and nitrogen, a residue of chlorine and nitrogen can remain on an exposed surface of the first insulator layer 41 at the bottom of the hole 30, as generally illustrated by a box 56 in FIG. 6.

The main purpose of adding the first sacrificial layer 51 and the second sacrificial layer 52, and then removing them using the first etch chemistry containing chlorine and nitrogen can be to create conditions so that the residue of chlorine and nitrogen remains on an exposed surface of the first insulator layer 41 at the bottom of the hole 30 (e.g., box 56).

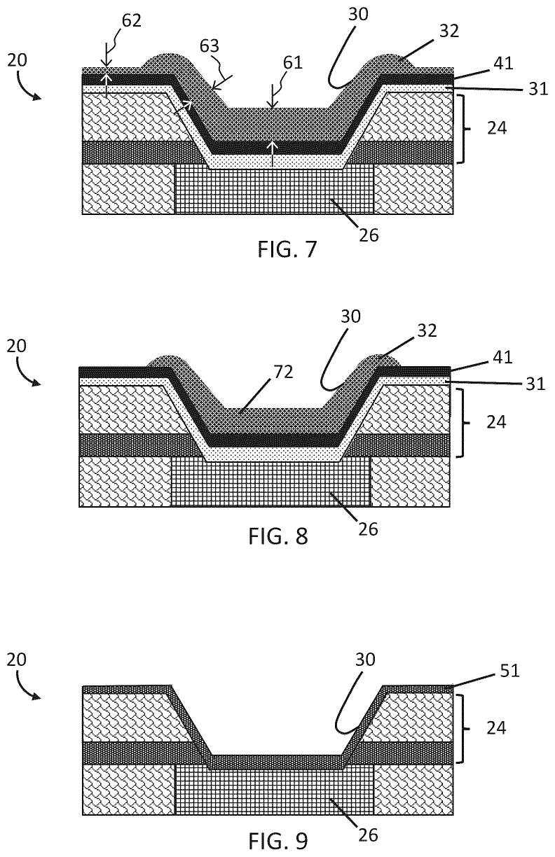

Referring to FIG. 7, while the residue of chlorine and nitrogen remains on an exposed surface of the first insulator layer 41 at the bottom of the hole (e.g., box 56 in FIG. 6), the initiation or starting of depositing a second metal electrode layer 32 on the first insulating layer 41 can be performed. Then, the remainder of the second metal electrode layer 32 can be deposited/formed. From experimental testing, it has been found that removal of the second sacrificial layer 52 (e.g., spin-on-glass) and the first sacrificial layer 51 (e.g., SiN) using an etch chemistry containing chlorine and nitrogen, followed by a deposition of metal nitride layer on the exposed first insulating layer 41 results in a faster and thicker deposition of the material(s) for a second metal electrode layer 32 at the bottom of the hole 30 where a residue of gases including the chlorine and nitrogen remains as residue at the bottom of the hole 30 when such deposition is started, as compared to the rate and thickness of material(s) deposition outside of the hole 30. For example, experimental testing as such using a method embodiment of the present disclosure using a titanium nitride layer as a first-deposited layer of the second metal electrode layer 32 followed by a second-deposited layer of tungsten for the second metal electrode layer 32, resulted in a first thickness 61 of the second metal electrode layer 32 at the bottom of the hole 30 of about 40 nm, while a second thickness 62 of the second metal electrode layer 32 on the top surface outside of the hole 30 and adjacent the hole 30 was about 6 nm, and while a third thickness 63 of the second metal electrode layer 32 on sidewalls of the hole 30 was about 20 nm. Thus, the experimental testing as such using a method embodiment of the present disclosure resulted in a first thickness 61 (40 nm) of the second metal electrode layer 32 at the bottom of the hole 30 being about 6.7 times greater than a second thickness 62 (6 nm) of the second metal electrode layer 32 on the top surface outside of the hole 30 and adjacent the hole 30.

Even though the second metal electrode layer 32 is illustrated in the drawings as a single layer, in some embodiments, this second metal electrode layer 32 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, such material(s) of a given second metal electrode layer 32 can include W, WSi, W(Si)N, TiN, TaN, CrN, NbN, VN, MON, and Ti(Al)N, layers thereof, mixtures thereof, laminates thereof, or generally any combination thereof, for example. In some embodiments, the second metal electrode layer 32 can include a metal nitride layer deposited first with metal layer deposited secondly on the first-deposited metal nitride layer. For example, in some embodiments, the second metal electrode layer 32 can include a titanium nitride layer deposited first, and with a tungsten layer deposited secondly on the titanium nitride layer. In some embodiments, the first-deposited layer of metal nitride for the second metal electrode layer 32 can be non-conductive or not a great conductor because it is formed on the first insulating layer 41, but still having good adhesion to subsequent deposited metal/conductive layer (e.g., tungsten, tungsten composition variations, or tungsten alternatives) of the second metal electrode layer 32, such as: AlN, Si₃N₄, BN, ZrN, HfN, TiSiN, layers thereof, mixtures thereof, laminates thereof, or generally any combination thereof, for example. In some embodiments, the first-deposited layer of the second metal electrode layer 32 can include a metal oxide, such as HfZrO, ZrO, layers thereof, mixtures thereof, laminates thereof, or generally any combination thereof, for example.

The thickness of the second metal electrode layer 32 can depend on the process flow integration. In some embodiments, a first-deposited layer of the second metal electrode layer 32 can be titanium nitride with a thickness at the bottom of the hole 30 of about 5 nm (+/−2 nm), and a second-deposited layer of the second metal electrode layer 32 can be tungsten with a thickness at the bottom of the hole 30 of more than 15 nm and with a target thickness outside of the hole of about 6 nm or less, for example.

In some embodiments, the second metal electrode layer 32 can be formed using PVD, CVD, PECVD, ALD, PEALD, or any combination thereof, for example. In some embodiments, a first-deposited layer, a second-deposited layer, or all of the second metal electrode layer 32 can be formed using CVD including a precursor of WF₆, WCl₅, WCl₆, or any combination thereof, for example. In some embodiments, a first-deposited layer, a second-deposited layer, or all of the second metal electrode layer can be formed using CVD with a process temperature in a range of 200° C. to 500° C., for example.

Referring to FIG. 8, the second metal electrode layer 32 can be etched back until or such that the second thickness (see e.g., second thickness 62 of FIG. 7) of the second metal electrode layer 32 on the top surface outside of the hole 30 and adjacent the hole 30 becomes zero, or until the second metal electrode layer 32 is removed sufficiently outside of the hole 30 to form a distinct second metal electrode 72 for the MIM device. This can be possible using a method embodiment of the present disclosure because of the large thickness variance of the second metal electrode layer 32 inside the hole 30 compared to outside the hole 30. And accordingly, a second metal electrode 72 for a MIM device can be formed without the use of a lithography mask for that second metal electrode 72, as illustrated in FIGS. 1-8.

In some embodiments, the etching of the second metal electrode layer 32 can have the following process conditions, for example: a step process time of about 60 seconds; a chamber pressure of about 30 mTorr, or in a range of 10 mTorr to 100 mTorr; an upper radio frequency (RF) Power of about 300 watts, or in a range of 100 watts to 1000 watts; a lower RF Power of about 100 watts, or in a range of 20 watts to 200 watts; a temperature of about 30° C., or in a range of 0° C. to 100° C.; a flow rate of Cl₂ of about 30 SCCM, or in a range of 50 SCCM to 500 SCCM; and a flow rate of Ar of about 150 SCCM, or in a range of 50 SCCM to 500 SCCM. In some embodiments, the etching of the second metal electrode layer can be a timed etch.

In some embodiments, after the etching of the second metal electrode layer 32 to form the second metal electrode 72, a first thickness of the second metal electrode 72 at the bottom of the hole 30 can be in a range of 20 nm to 30 nm, a second thickness of the second metal electrode layer 32 on the top surface outside of the hole 30 and adjacent the hole 30 can be zero (i.e., removed), and a third thickness of the second metal electrode 72 on sidewalls of the hole 30 can be greater than 5 nm (e.g., at the frontage of the via/hole).

The technique described above for forming a second metal electrode 72 can also be used for forming a first (lower) metal electrode for a MIM device. Accordingly, FIGS. 1, 2, 9-14 illustrate intermediate structures for making a MIM device in accordance with a method embodiment of the present disclosure.

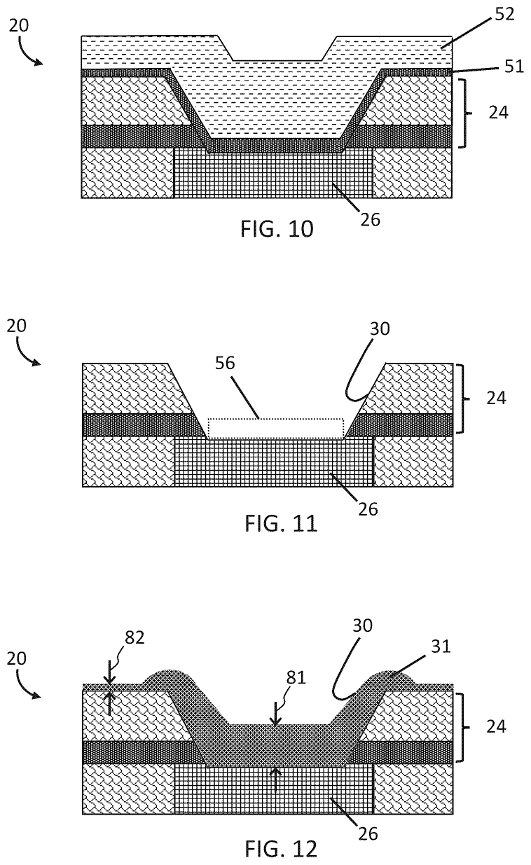

Referring to FIG. 9, and starting with the intermediate structures shown and described above regarding FIGS. 1 and 2, a first sacrificial layer 51 can be deposited in the hole 30. The first sacrificial layer 51 can be silicon nitride that is conformally deposited using CVD, for example. Referring to FIG. 10, a second sacrificial layer 52 can be deposited on the first sacrificial layer 51. In some embodiments, the second sacrificial layer 52 can be formed by spin coating to form a spin-on-glass layer (e.g., silicon dioxide), for example. The intermediate structure of FIG. 10 can be baked in a temperature range of 400° C. to 450° C., for example.

Referring to FIG. 11, the second sacrificial layer 52 and the first sacrificial layer 51 can be removed using a first etch chemistry containing chloride (Cl₂) and nitrogen (N₂). The etching can be a wet etch, a dry etch, reactive ion etching (RIE), plasma etching, or any combination thereof, for example. Other etch processes using other etch chemistries can be used during the removal of the second sacrificial layer 52 and the first sacrificial layer 51, with the removing at least concluding with etching using the first etch chemistry containing chlorine and nitrogen. After the etching using the first etch chemistry containing chlorine and nitrogen, a residue of chlorine and nitrogen can remain on an exposed surface of the contact 26 at the bottom of the hole 30, as generally illustrated by a box 56 in FIG. 11.

Referring to FIG. 12, while the residue of chlorine and nitrogen remains at the bottom of the hole 30 (e.g., box 56 in FIG. 11), the deposition of a first metal electrode layer 31 can be initiated in the hole 30. Using a method embodiment of the present disclosure can result in a first thickness 81 of the first metal electrode layer 31 at the bottom of the hole 30 being at least five to six times greater than a second thickness 82 of the first metal electrode layer 31 on the top surface outside of the hole 30 and adjacent the hole 30.

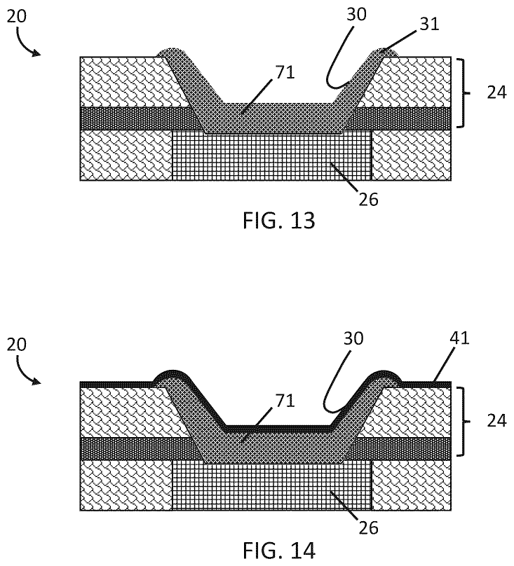

Referring to FIG. 13, the first metal electrode layer 31 can be etched back until or such that the second thickness (see e.g., second thickness 82 in FIG. 12) of the first metal electrode layer 31 on the top surface outside of the hole 30 and adjacent the hole 30 becomes zero, or until the first metal electrode layer 31 is removed sufficiently outside of the hole 30 to form a distinct first metal electrode 71 for the MIM device. This can be possible using a method embodiment of the present disclosure because of the large thickness variance of the first metal electrode layer 31 inside the hole 30 compared to outside the hole 30. And accordingly, a first metal electrode 71 for a MIM device can be formed without the use of a separate lithography mask operation for defining and isolating the first metal electrode 71, as illustrated in FIGS. 1, 2, and 9-13.

Referring to FIG. 14, a first insulating layer 41 can be conformally deposited in the hole 30 on the first metal electrode 71, which can form an intermediate structure of a MIM device. Thereafter, a method embodiment of the present disclosure can proceed to form a second metal electrode 72 for the MIM device, as described above relating to and illustrated by FIGS. 3-8, for example.

In some embodiments, a first insulating layer 41 can be conformally deposited on and over the intermediate structure of FIG. 12, as another alternative process flow integration, in accordance with a method embodiment of the present disclosure, for example.

In some embodiments, a hole 30 for forming a MIM device can have a minimum diameter of about 30 nm with a height of not more than 90 nm, for example. In some embodiments, as the aspect ratio of a hole 30 increases (e.g., as the hole width decreases and/or as the hole depth increases), PECVD can be used instead of CVD or in combination with CVD (e.g., PECVD first) for various depositions of various layers in a method embodiment. In some embodiments, as the aspect ratio of a hole 30 increases (e.g., as the hole width decreases and/or as the hole depth increases), ALD can be used instead of CVD or in combination with CVD (e.g., ALD first) for various depositions of various layers in a method embodiment. In some embodiments, there can be a limit to the aspect ratio of the hole 30 for allowing the effect of a remnant of Cl₂ and/or N₂ in a bottom of a hole 30 (e.g., box 56) when starting the formation/deposition of an electrode layer.

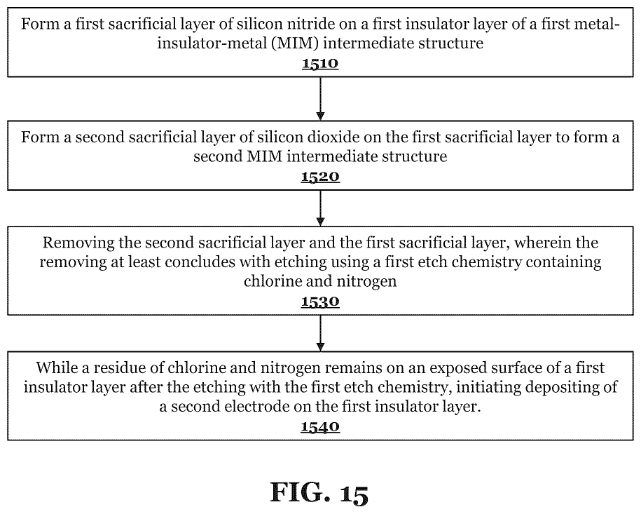

FIG. 15 illustrates a flow chart implementing the forming of an electrode for a MIM device in accordance with an embodiment of the present disclosure. In an embodiment, a method for making a semiconductor device includes forming a first sacrificial layer of silicon nitride on a first insulator layer of a first metal-insulator-metal (MIM) intermediate structure, where the first MIM intermediate structure further includes a first electrode, and where the first insulator layer is on the first electrode (box 1510). The method includes forming a second sacrificial layer of silicon dioxide on the first sacrificial layer to form a second MIM intermediate structure (box 1520). The method includes removing the second sacrificial layer and the first sacrificial layer, where the removing at least concludes with etching using a first etch chemistry containing chlorine and nitrogen (box 1530). The method includes, while a residue of chlorine and nitrogen remains on an exposed surface of the first insulator layer after the etching with the first etch chemistry, initiating depositing of a second electrode on the first insulator layer (box 1540).

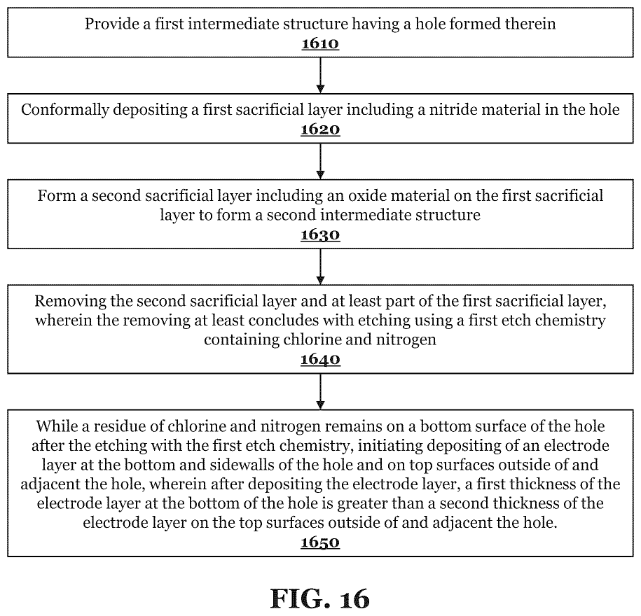

FIG. 16 illustrates a flow chart implementing the forming of an electrode for a MIM device in accordance with an embodiment of the present disclosure. In an embodiment, a method for making a semiconductor device includes providing a first intermediate structure having a hole formed therein (box 1610). The method includes conformally depositing a first sacrificial layer including a nitride material in the hole (box 1620). The method includes forming a second sacrificial layer including an oxide material on the first sacrificial layer to form a second intermediate structure (box 1630). The method includes removing the second sacrificial layer and at least part of the first sacrificial layer, where the removing at least concludes with etching using a first etch chemistry containing chlorine and nitrogen (box 1640). The method includes, while a residue of chlorine and nitrogen remains on a bottom surface of the hole after the etching with the first etch chemistry, initiating depositing of an electrode layer at the bottom and sidewalls of the hole and on top surfaces outside of and adjacent the hole, where after depositing the electrode layer, a first thickness of the electrode layer at the bottom of the hole is greater than a second thickness of the electrode layer on the top surfaces outside of and adjacent the hole (box 1650).

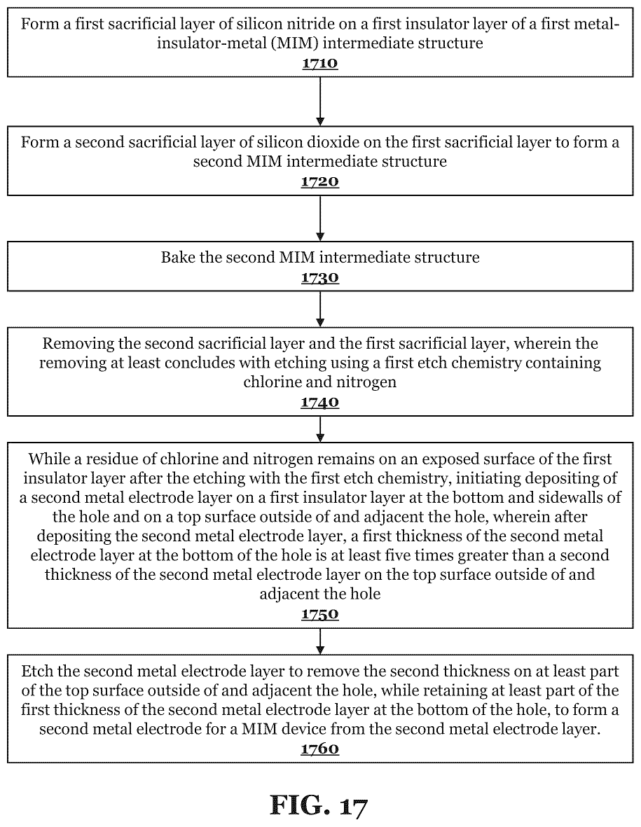

FIG. 17 illustrates a flow chart implementing the forming of an electrode for a MIM device in accordance with an embodiment of the present disclosure. In an embodiment, a method for making a semiconductor device includes forming a first sacrificial layer of silicon nitride on a first insulator layer of a first metal-insulator-metal (MIM) intermediate structure, where the first MIM intermediate structure further includes a first metal electrode formed on a bottom and at least partially on sidewalls of a hole, and where the first insulator layer is conformally on and covering the first metal electrode (box 1710). The method includes forming a second sacrificial layer of silicon dioxide on the first sacrificial layer to form a second MIM intermediate structure (box 1720). The method includes baking the second MIM intermediate structure (box 1730). The method includes removing the second sacrificial layer and the first sacrificial layer, where the removing at least concludes with etching using a first etch chemistry containing chlorine and nitrogen (box 1740). The method includes, while a residue of chlorine and nitrogen remains on an exposed surface of the first insulator layer after the etching with the first etch chemistry, initiating depositing of a second metal electrode layer on the first insulator layer at the bottom and sidewalls of the hole and on a top surface outside of and adjacent the hole, where the second metal electrode layer includes a metal nitride layer being first deposited for the depositing of the second metal electrode layer, and where after depositing the second metal electrode layer, a first thickness of the second metal electrode layer at the bottom of the hole is at least five times greater than a second thickness of the second metal electrode layer on the top surface outside of and adjacent the hole (box 1750). The method includes etching the second metal electrode layer to remove the second thickness on at least part of the top surface outside of and adjacent the hole, while retaining at least part of the first thickness of the second metal electrode layer at the bottom of the hole, to form a second metal electrode for a MIM device from the second metal electrode layer (box 1760).

The embodiments described in FIGS. 15-17 may be implemented as further described using FIGS. 1-14.

More example embodiments of the present disclosure are summarized here. Other embodiments can also be understood from the entirety of the specification as well as the claims filed herein.

Example 1. A method for forming a semiconductor device including: forming a first sacrificial layer of silicon nitride on a first insulator layer of a first metal-insulator-metal (MIM) intermediate structure, where the first MIM intermediate structure further includes a first electrode, where the first insulator layer is on the first electrode; forming a second sacrificial layer of silicon dioxide on the first sacrificial layer to form a second MIM intermediate structure; removing the second sacrificial layer and the first sacrificial layer, where the removing at least concludes with etching using a first etch chemistry containing chlorine and nitrogen; and while a residue of chlorine and nitrogen remains on an exposed surface of the first insulator layer after the etching with the first etch chemistry, initiating depositing of a second electrode on the first insulator layer.

Example 2. The method of example 1, further including baking the second MIM intermediate structure.

Example 3. The method of one of examples 1 or 2, where the baking includes heating the second MIM intermediate structure within a temperature range of 400° C. to 450° C.

Example 4. The method of one of examples 1 to 3, where the first MIM intermediate structure includes a hole formed in a first dielectric layer, where the first electrode and the first insulator layer are conformally on a bottom and sidewalls of the hole.

Example 5. The method of one of examples 1 to 4, where the depositing of the second electrode includes depositing a second electrode layer at the bottom and sidewalls of the hole and on top surfaces outside of and adjacent the hole, and where a first thickness of the second electrode layer at the bottom of the hole is greater than a second thickness of the second electrode layer on the top surfaces outside of and adjacent the hole.

Example 6. The method of one of examples 1 to 5, further including etching the second electrode layer to reduce the second thickness at least until the first insulating layer is exposed on at least part of the top surfaces outside of and adjacent the hole.

Example 7. The method of one of examples 1 to 6, where the first thickness is at least six times greater than the second thickness.

Example 8. The method of one of examples 1 to 7, where the second electrode layer includes a titanium nitride layer and a tungsten layer, where the titanium nitride layer is deposited first for the depositing of the second electrode layer, where the first thickness is 40 nm, and where the second thickness is 6 nm.

Example 9. The method of one of examples 1 to 8, where the first thickness is greater than a third thickness of the second electrode layer on an upper location of the sidewalls of the hole.

Example 10. The method of one of examples 1 to 9, where the first thickness is at least twice thicker than the third thickness.

Example 11. The method of one of examples 1 to 10, where the first thickness is 40 nm and the third thickness is 20 nm.

Example 12. The method of one of examples 1 to 11, where the forming of the second sacrificial layer includes spin coating to form a spin-on-glass layer.

Example 13. A method for forming a semiconductor device including: providing a first intermediate structure having a hole formed therein; conformally depositing a first sacrificial layer including a nitride material in the hole; forming a second sacrificial layer including an oxide material on the first sacrificial layer to form a second intermediate structure; removing the second sacrificial layer and at least part of the first sacrificial layer, where the removing at least concludes with etching using a first etch chemistry containing chlorine and nitrogen; and while a residue of chlorine and nitrogen remains on a bottom of the hole after the etching with the first etch chemistry, initiating depositing of at least a first portion of an electrode layer at the bottom and sidewalls of the hole and on top surfaces outside of and adjacent the hole, where after depositing the electrode layer, a first thickness of the electrode layer at the bottom of the hole is greater than a second thickness of the electrode layer on the top surfaces outside of and adjacent the hole.

Example 14. The method of example 13, further including etching the electrode layer to remove the second thickness on at least part of the top surfaces outside of and adjacent the hole.

Example 15. The method of one of examples 13 or 14, where the first thickness is at least six times greater than the second thickness.

Example 16. The method of one of examples 13 to 15, further including baking the second intermediate structure, where the first sacrificial layer includes silicon nitride, and where the second sacrificial layer includes spin-on-glass.

Example 17. The method of one of examples 13 to 16, where the electrode layer includes a first metal electrode, and further including: forming a first insulating layer on the first metal electrode; and forming a second metal electrode on the first insulating layer to form a metal-insulator-metal structure.

Example 18. The method of one of examples 13 to 17, where the first intermediate structure includes a first metal electrode and a first insulator layer, both being conformal on the bottom and sidewalls of the hole, where the first insulator layer is on the first metal electrode, and where the electrode layer includes a second metal electrode to form a metal-insulator-metal structure.

Example 19. A method for forming a semiconductor device including: forming a first sacrificial layer of silicon nitride on a first insulator layer of a first metal-insulator-metal (MIM) intermediate structure, where the first MIM intermediate structure further includes a first metal electrode formed on a bottom and at least partially on sidewalls of a hole, where the first insulator layer is conformally on and covering the first metal electrode; forming a second sacrificial layer of silicon dioxide on the first sacrificial layer to form a second MIM intermediate structure; baking the second MIM intermediate structure; removing the second sacrificial layer and the first sacrificial layer, where the removing at least concludes with etching using a first etch chemistry containing chlorine and nitrogen; while a residue of chlorine and nitrogen remains on an exposed surface of the first insulator layer after the etching with the first etch chemistry, initiating depositing of a second metal electrode layer on the first insulator layer at the bottom and sidewalls of the hole and on a top surface outside of and adjacent the hole, the second metal electrode layer includes a metal nitride layer being first deposited for the depositing of the second metal electrode layer, and where after the depositing of the second metal electrode layer, a first thickness of the second metal electrode layer at the bottom of the hole is at least five times greater than a second thickness of the second metal electrode layer on the top surface outside of and adjacent the hole; and etching the second metal electrode layer to remove the second thickness on at least part of the top surface outside of and adjacent the hole, while retaining at least part of the first thickness of the second metal electrode layer at the bottom of the hole, to form a second metal electrode for a MIM device from the second metal electrode layer.

Example 20. The method of example 19, where after the etching of the second metal electrode layer, portions of the second metal electrode layer remain on at least part of the sidewalls of the hole, such that the second metal electrode is on the bottom of the hole and on at least part of the sidewalls of the hole.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

1. A method for forming a semiconductor device, the method comprising:
forming a first sacrificial layer of silicon nitride on a first insulator layer of a first metal-insulator-metal (MIM) intermediate structure, wherein the first MIM intermediate structure further includes a first electrode, wherein the first insulator layer is on the first electrode;
forming a second sacrificial layer of silicon dioxide on the first sacrificial layer to form a second MIM intermediate structure;
removing the second sacrificial layer and the first sacrificial layer, wherein the removing at least concludes with etching using a first etch chemistry containing chlorine and nitrogen; and
while a residue of chlorine and nitrogen remains on an exposed surface of the first insulator layer after the etching with the first etch chemistry, initiating depositing of a second electrode on the first insulator layer.

2. The method of claim 1, further comprising baking the second MIM intermediate structure.

3. The method of claim 2, wherein the baking comprises heating the second MIM intermediate structure within a temperature range of 400° C. to 450° C.

4. The method of claim 1, wherein the first MIM intermediate structure includes a hole formed in a first dielectric layer, wherein the first electrode and the first insulator layer are conformally on a bottom and sidewalls of the hole.

5. The method of claim 4, wherein the depositing of the second electrode comprises depositing a second electrode layer at the bottom and sidewalls of the hole and on top surfaces outside of and adjacent the hole, and wherein a first thickness of the second electrode layer at the bottom of the hole is greater than a second thickness of the second electrode layer on the top surfaces outside of and adjacent the hole.

6. The method of claim 5, further comprising etching the second electrode layer to reduce the second thickness at least until the first insulating layer is exposed on at least part of the top surfaces outside of and adjacent the hole.

7. The method of claim 5, wherein the first thickness is at least six times greater than the second thickness.

8. The method of claim 7, wherein the second electrode layer includes a titanium nitride layer and a tungsten layer, wherein the titanium nitride layer is deposited first for the depositing of the second electrode layer, wherein the first thickness is 40 nm, and wherein the second thickness is 6 nm.

9. The method of claim 5, wherein the first thickness is greater than a third thickness of the second electrode layer on an upper location of the sidewalls of the hole.

10. The method of claim 9, wherein the first thickness is at least twice thicker than the third thickness.

11. The method of claim 10, wherein the first thickness is 40 nm and the third thickness is 20 nm.

12. The method of claim 1, wherein the forming of the second sacrificial layer comprises spin coating to form a spin-on-glass layer.

13. A method for forming a semiconductor device, the method comprising:
providing a first intermediate structure having a hole formed therein;
conformally depositing a first sacrificial layer including a nitride material in the hole;
forming a second sacrificial layer including an oxide material on the first sacrificial layer to form a second intermediate structure;
removing the second sacrificial layer and at least part of the first sacrificial layer, wherein the removing at least concludes with etching using a first etch chemistry containing chlorine and nitrogen; and
while a residue of chlorine and nitrogen remains on a bottom of the hole after the etching with the first etch chemistry, initiating depositing of at least a first portion of an electrode layer at the bottom and sidewalls of the hole and on top surfaces outside of and adjacent the hole, wherein after depositing the electrode layer, a first thickness of the electrode layer at the bottom of the hole is greater than a second thickness of the electrode layer on the top surfaces outside of and adjacent the hole.

14. The method of claim 13, further comprising etching the electrode layer to remove the second thickness on at least part of the top surfaces outside of and adjacent the hole.

15. The method of claim 13, wherein the first thickness is at least six times greater than the second thickness.

16. The method of claim 13, further comprising baking the second intermediate structure, wherein the first sacrificial layer includes silicon nitride, and wherein the second sacrificial layer includes spin-on-glass.

17. The method of claim 13, wherein the electrode layer includes a first metal electrode, and further comprising:
forming a first insulating layer on the first metal electrode; and
forming a second metal electrode on the first insulating layer to form a metal-insulator-metal structure.

18. The method of claim 13, wherein the first intermediate structure includes a first metal electrode and a first insulator layer, both being conformal on the bottom and sidewalls of the hole, wherein the first insulator layer is on the first metal electrode, and wherein the electrode layer includes a second metal electrode to form a metal-insulator-metal structure.

19. A method for forming a semiconductor device, the method comprising:
forming a first sacrificial layer of silicon nitride on a first insulator layer of a first metal-insulator-metal (MIM) intermediate structure, wherein the first MIM intermediate structure further includes a first metal electrode formed on a bottom and at least partially on sidewalls of a hole, wherein the first insulator layer is conformally on and covering the first metal electrode;
forming a second sacrificial layer of silicon dioxide on the first sacrificial layer to form a second MIM intermediate structure;
baking the second MIM intermediate structure;
removing the second sacrificial layer and the first sacrificial layer, wherein the removing at least concludes with etching using a first etch chemistry containing chlorine and nitrogen;
while a residue of chlorine and nitrogen remains on an exposed surface of the first insulator layer after the etching with the first etch chemistry, initiating depositing of a second metal electrode layer on the first insulator layer at the bottom and sidewalls of the hole and on a top surface outside of and adjacent the hole, the second metal electrode layer includes a metal nitride layer being first deposited for the depositing of the second metal electrode layer, and wherein after the depositing of the second metal electrode layer, a first thickness of the second metal electrode layer at the bottom of the hole is at least five times greater than a second thickness of the second metal electrode layer on the top surface outside of and adjacent the hole; and
etching the second metal electrode layer to remove the second thickness on at least part of the top surface outside of and adjacent the hole, while retaining at least part of the first thickness of the second metal electrode layer at the bottom of the hole, to form a second metal electrode for a MIM device from the second metal electrode layer.

20. The method of claim 19, wherein after the etching of the second metal electrode layer, portions of the second metal electrode layer remain on at least part of the sidewalls of the hole, such that the second metal electrode is on the bottom of the hole and on at least part of the sidewalls of the hole.
